(19) United States
(12) Patent Application Publication
(10) Pub. No.: US 2020/0001325 A1
(43) Pub. Date: Jan. 2, 2020

(54) COBALT OXIDE- ANTIMONY TIN OXIDE (COO-ATO) ANTI-REFLECTING COATING

(71) Applicants: SYLVIA WILSON THOMAS, Orlando, FL (US); MANOPRIYA DEVISETTY SUBRAMANYAM, Tampa, FL (US); RIDITA RAHMAN KHAN, Tampa, FL (US); NIRMITA ROY, Tampa, FL (US); BRANDON DEMAR RICHARD, Allen, TX (US)

(72) Inventors: SYLVIA WILSON THOMAS, Orlando, FL (US); MANOPRIYA DEVISETTY SUBRAMANYAM, Tampa, FL (US); RIDITA RAHMAN KHAN, Tampa, FL (US); NIRMITA ROY, Tampa, FL (US); BRANDON DEMAR RICHARD, Allen, TX (US)

(73) Assignee: UNIVERSITY OF SOUTH FLORIDA, Tampa, FL (US)

(21) Appl. No.: 16/362,440

(22) Filed: Mar. 22, 2019

Related U.S. Application Data
(60) Provisional application No. 62/692,272, filed on Jun. 29, 2018.

(51) Int. Cl. B05D 5/06; C23C 14/06; B05D 7/24; H01L 21/02

(52) U.S. Cl. CPC B05D 5/061; C23C 14/0605; B05D 7/24; C23C 14/3407; H01L 21/02282; H01L 21/02266; H01L 21/02115; H01L 21/02194

(57) ABSTRACT

Methods and devices related to the enhancement the light absorbance characteristics of an optoelectronic device are provided. A method can comprise providing a CoO-ATO sol-gel solution to coat on a silicon substrate. Carbon can be sputtered onto the silicon substrate, and the CoO-ATO sol-gel solution can be deposited on a surface of the carbon deposited silicon substrate. The deposition of the solution can be by spin coating to achieve a uniform thickness of the solution on the surface of the carbon deposited substrate.

### CROSS-REFERENCE TO RELATED APPLICATION

This application claims the benefit of U.S. Provisional Application Ser. No. 62/692,272, filed Jun. 29, 2018, the disclosure of which is hereby incorporated by reference in its entirety, including all figures, tables, and drawings.

### BACKGROUND

The efficiency of a photovoltaic device is dependent upon minimizing the amount of incident light reflected from the device. When incident light strikes the surface of a semiconductor, the light waves are either absorbed into the semiconductor material or become partially reflected. Partial reflection is an important consideration in solar cells where transmitted light energy into the semiconductor device is being converted into electrical energy. Light reflected from an optoelectronic device is not absorbed for conversion into electrical energy and the efficiency of the device is reduced.

Present photovoltaic technology includes wafer based thick film solar cells, thin film solar cells, and ultra-thin film solar cells. Thin film silicon-based photovoltaic technology, however, still shows inferior performance compared to silicon wafer based technology, mainly because of the low near band gap absorption of silicon.

### BRIEF SUMMARY

Certain embodiments of the subject invention describe the fabrication of CoO-ATO layers (micro-nano thin films and fiber membranes) as antireflective coatings (ARC) and absorbing layers for various optoelectronic systems, such as solar cells, optical lenses, and photodetectors. CoO-ATO thin films (100-500 nm) and nanofiber membranes (fiber diameters ˜10-200 nm) can be fabricated via spin coating and electrospinning, respectively.

Other embodiments provide an optoelectronic device that incorporates metallic nanoparticles into a thin film photovoltaic cell. Metal nanoparticles with high scattering properties can be employed to enhance light trapping characteristics and the optical path length (OPL). The metallic nanoparticles enable enhanced absorption of light waves, reduced surface reflectance, and improvement of the overall cell efficiency of the optoelectronic devices.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is an illustration of the electrospinning set-up.

FIG. 2 is a scanning electron microscope (SEM) image of nanofibers spun from a solution comprising 15% polystyrene (PS), 10% cobalt oxide (CoO), and 75% toluene/antimony tin oxide (ATO).

FIG. 3 is an SEM image of nanofibers spun from a solution comprising 10% PS, 10% CoO, and 80% toluene/ATO.

FIG. 4 is an SEM picture of nanofibers spun from a solution comprising 20% PS, 10% CoO, and 70% toluene/ATO.

FIG. 5 is an SEM image of a fiber mesh spun from a solution comprising 20% PS, 10% CoO, and 70% toluene/ATO: 70%.

FIG. 6 is an SEM image of nanofibers spun from a solution comprising 15% PS, 10% CoO, and 75% D-limonene/ATO.

FIG. 7 is an SEM image of nanofibers spun from a solution comprising 10% PS, 10% CoO, and 80% D-limonene/ATO.

FIG. 8 is an SEM image of a PS mesh made with a solution comprising 15% PS, 10% CoO, and 75% toluene.

FIG. 9 is a two dimensional color graph showing the temperature change in the interfaces at maximum exposure from a Nd:YAG laser point source.

FIG. 10 is a table of COMSOL finite element simulation parameters.

FIG. 11 is a plot of the reflectivity of tin oxide coated carbon surfaces versus time.

FIG. 12 is a diagram of the ATO sol-gel/carbon/silicon sample layouts used for electrical testing.

FIG. 13 is an EDS quantitative element composition analysis of (ATO(Co₂O₃)) after 500° C. heat treatment.

FIG. 14 is a plot of an IR spectra of (ATO(Co₂O₃)) heat treated from 200-500° C.

FIG. 15 is a plot of Raman spectroscopy of ATO sol-gel thin films heat treated at 200 and 500° C., respectively.

FIG. 16 is an image of (ATO(0.1% Co₂O₃)) after a 300° C. heat treatment.

FIG. 17 is a plot of a Raman spectroscopy of (ATO(Co₂O₃)) after one cycle of spin coating/heat treatment at 200° C.

FIG. 18 is a plot of Raman spectroscopy of (ATO(Co₂O₃)) after one cycle of spin coating/heat treatment at 500° C.

FIG. 19 is a plot of the hemispherical reflectance of (ATO(Co₂O₃)) sol-gel coatings on woven carbon fiber mats.

FIG. 20 is a plot of the reflectance of ATO sol-gel coatings with varying Co₂O₃ doping concentrations.

FIG. 21 is a plot of the reflectance of (ATO(x % Co₂O₃)) sol-gel coatings with varying Co₂O₃ doping concentrations at an 80° incident angle.

FIG. 22 is a plot of the reflectance of (ATO(x % Co₂O₃)) sol-gel coatings with varying Co₂O₃ doping concentrations at an 85° incident angle.

FIG. 23 is a plot of the reflectance of (ATO(x % Co₂O₃)) sol-gel coatings with varying Co₂O₃ doping concentrations at a 90° incident angle.

FIG. 24 is a plot of the reflectance of (ATO(x % Co₂O₃)) sol-gel coatings with varying Co₂O₃ doping concentrations at a 95° incident angle.

FIG. 25 is a plot of the reflectance of (ATO(x % Co₂O₃)) sol-gel coatings with varying Co₂O₃ doping concentrations at a 100° incident angle.

FIG. 26 is an atomic force microscopy three dimensional image of the topography a thin film.

FIG. 27 is an atomic force microscopy flattened height image of a thin film.

FIG. 28 is an atomic force microscopy image of a thin film.

FIG. 29 is an atomic force microscopy image of a thin film, a plot of an x and y height analysis, and a plot describing a spectrum analysis.

FIG. 30 is a diagram illustrating a design of a plasmonic solar cell.

FIG. 31 is a plot of the transmission coefficient, reflection coefficient, and absorption coefficient of a 3 μm silicon film.

FIG. 32a is plot of the transmission coefficient, reflection coefficient, and absorption of thin film silicon covered with silver nanospheres having radius of 167 nm. FIG. 32b is plot of the transmission coefficient, reflection coefficient, and absorption of thin film silicon covered with silver nanospheres having radius of 180 nm. FIG. 32c is plot of the transmission coefficient, reflection coefficient, and absorption of thin film silicon covered with silver nanospheres having radius of 200 nm. FIG. 32d is plot of the transmission coefficient, reflection coefficient, and absorption of thin film silicon covered with silver nanospheres having radius of 220 nm.

FIG. 33a is plot of the transmission coefficient, reflection coefficient, and absorption of thin film silicon covered with aluminum nanospheres having radius of 167 nm. FIG. 33b is plot of the transmission coefficient, reflection coefficient, and absorption of thin film silicon covered with aluminum nanospheres having radius of 180 nm. FIG. 33c is plot of the transmission coefficient, reflection coefficient, and absorption of thin film silicon covered with aluminum nanospheres having radius of 200 nm. FIG. 33d is plot of the transmission coefficient, reflection coefficient, and absorption of thin film covered with aluminum nanospheres having radius of 220 nm.

### DETAILED DESCRIPTION

The following disclosure and exemplary embodiments are presented to enable one of ordinary skill in the art to make and use a CoA/ATO layer or metallic nanoparticle layer for an optoelectronic device according to the subject invention. Various modifications to the embodiments will be readily apparent to those skilled in the art and the generic principles herein may be applied to other embodiments. Thus, the devices and methods related to the disclosure and exemplary embodiments are not intended to be limited to the embodiments shown, but are to be accorded the widest scope consistent with the principles and features described herein.

In one embodiment, a method of fabricating a CoO-ATO layer comprises a solution of polystyrene (PS), cobalt oxide (CoO), toluene, and antimony tin oxide (ATO). An initial step can be to measure the solvent and the polymer in a desired percent-by-weight ratio. The weight of polystyrene can be measured to 0.0001 of a gram. Toluene (ATO) can be measured and added to the solvent and polymer. Similarly, the required amount of cobalt oxide can be measured and added.

The solution can be stirred for 10 minutes or until the cobalt oxide is completely blended into the solution. After the solution is prepared, a syringe can be loaded with the solution for electrospinning.

In another embodiment, the solution comprises a D-limonene solution. The required weight of polystyrene can be measured to 0.0001 of a gram. Afterwards the ATO can be added to the D-limonene solution. A CoO solution can be added to the D-limonene solution and the ATO and the entire solution can be stirred. D-limonene takes a longer time to dissolve than PS and the stirring time should be approximately one hour. The stirring should continue until all of the materials are blended well together. After stirring is complete, the solution can be loaded in a syringe for electrospinning.

The experimental setup as shown in FIG. 1 comprises a voltage regulator 100, a syringe pump 110, and a collector plate 120. A base (not shown), for example an aluminum foil, can be wrapped on the plate 120. The voltage regulator 100 allows for varying the voltage. High voltages are required for electrospinning to generate strong electric fields between the needle 130 and the collector plate 120. The positive AC electrode is connected to the syringe 140 and the neutral electrode is connected to the collector plate 120. When the solution 150 in the needle 130 is pumped out, the solution 150 is charged up by the high voltage supply 100 and the charged solution is collected on the collector plate 120. The syringe pump 110 is a programmable infusion device and can be set to a desired volume of solution 150 to be ejected per unit of time.

Characteristics of the fiber formation can vary depending on parameters such as molecular weight of the polymer, infusion rate, concentration, voltage applied, viscosity of the solution, homogeneity of the solution, and current that is passed through the solution.

Polystyrene and D-limonene can be mixed in different proportions (percent by weight) and electrospun. Antimony doped tin oxide comprises solid particles dispersed in a liquid medium. ATO can comprise a toluene solvent. While electrospinning, the quantity of nanofiber produced per minute using toluene is significantly higher than the quantity obtained when D-limonene is used as a solvent.

Voltages in the range of 10 kV to 30 kV can be used in the electrospinning process. The high voltages correspond to a strong electric field between the needle and the collector plate. Voltages of 1 to 15 kV result in diminished nanofiber formation. High voltages near 28 kV can result in nanofibers that do not land on the collector plate. In one embodiment, the controlled deposition was optimized at 20 kV for the D-limonene based solutions and at 25 kV for the toluene based solutions.

The distance from the tip of the needle to the collector plate is another factor in electrospinning. D-limonene takes a long time to evaporate and placing the collector plate too close to the needle makes nanofiber formation difficult. If the distance is less than 20 cm, the solvent does not evaporate and falls on the collector plate. As unformed nanofiber continues to deposit on the previous nanofiber, both merge and form a thin layer of the solution. This can continue and in the end of the electrospinning process and a thin coating of the solution is formed on the collector. Toluene evaporates more readily than D-limonene and distance of 15 cm from the needle tip to the collector can be used.

Stirring increases the homogeneity of the solution. For a toluene based solution, stirring does not significantly affect nanofiber formation. On the other hand, for a D-limonene solution, a minimum of 1 hour of stirring should be performed. If the solution is not stirred long enough, the nanofiber formation at the needle tip is not consistent. Initially, nanofiber forms for the first minute and afterwards the solution either solidifies at the needle tip or drips to the floor.

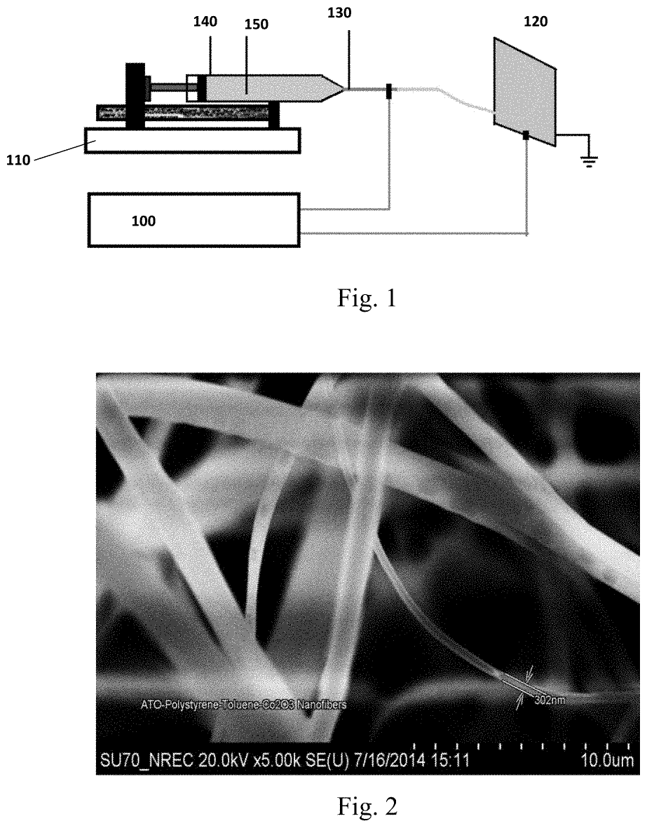

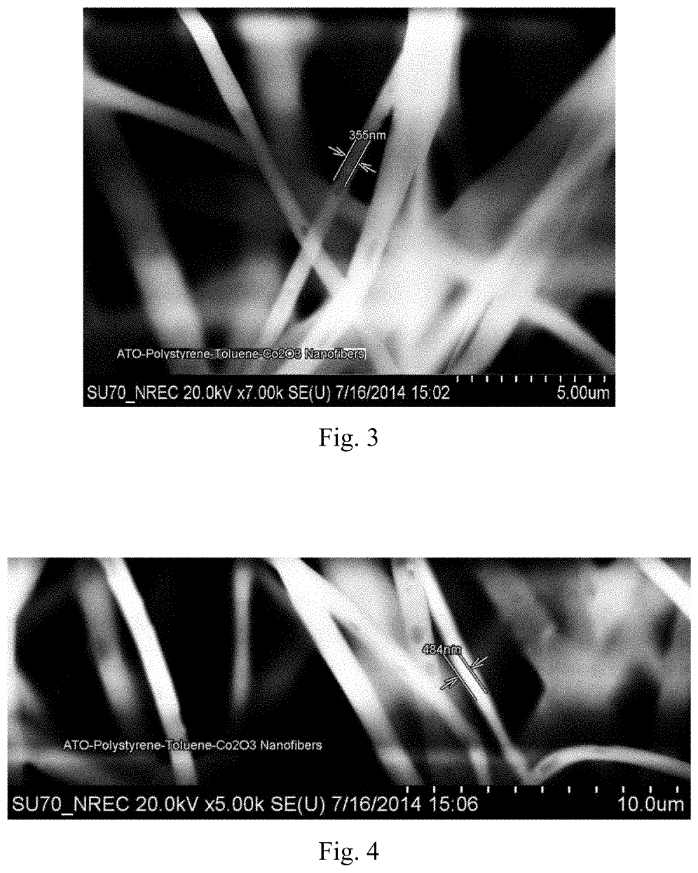

FIG. 2 is an SEM image of nanofibers spun from a solution comprising 15% PS, 10% CoO, and 75% toluene/ATO. The minimum diameter observed is 302 nm from this solution. FIG. 3 is an SEM image of nanofibers spun from a solution comprising 10% PS, 10% CoO, and 80% toluene/ATO.

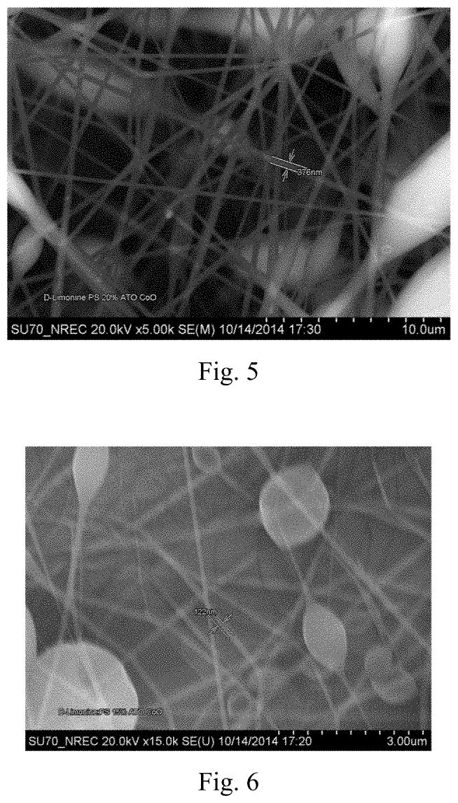

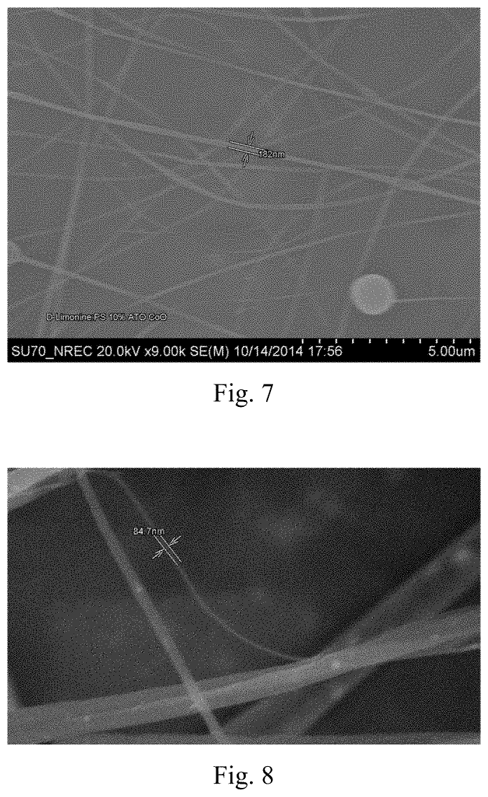

FIG. 4 is a SEM image of nanofibers spun from a solution comprising 20% PS, 10% CoO, and 70% toluene/ATO. The minimum diameter observed is 464 nm. FIG. 5 is an SEM image of a fiber mesh spun with a solution comprising 20% PS, 10% CoO, and 70% toluene/ATO. FIG. 6 shows that beading was more prominent in nanofibers spun from a solution of 15% PS, 10% CoO, and 75% D-limonene/ATO: 75%. FIG. 7 is an SEM image of nanofibers spun from a solution comprising 10% PS, 10% CoO, and 80% D-limonene/ATO. FIG. 8 is an SEM picture of nanofibers made from a solution comprising 15% PS, 10% CoO, and 75% toluene.

D-limonene and toluene evaporate as the nanofibers start forming at the needle tip. There is a difference in time required for spinning nanofibers from D-limonene based solutions and toluene based solutions. Nanofibers from the toluene based solutions are formed more quickly because as the nanofibers are formed at the needle tip and the solution evaporates. The D-limonene does not evaporate as quickly as the toluene. Because of this the infusion rate has to be less than toluene, approximately 20 μl/min.

In an embodiment of the subject invention, sol-gel solutions of undoped ATO and ATO with a 0.1% Co₂O₃ dopant level (ATO(0.1% Co₂O₃)) can be deposited on carbon/silicon substrates. The enhanced effect of using cobalt oxide (Co₂O₃) as a dopant in ATO sol-gel coatings on carbon surfaces at low annealing temperatures (200-300° C.) is presumed to be caused by the crystallinity of the materials, the increase in grain size, and the low degradation of phase composition.

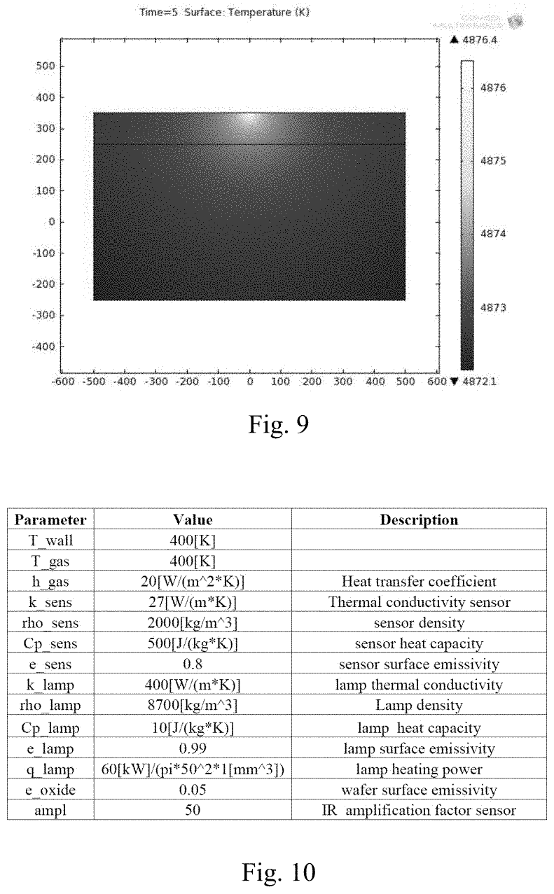

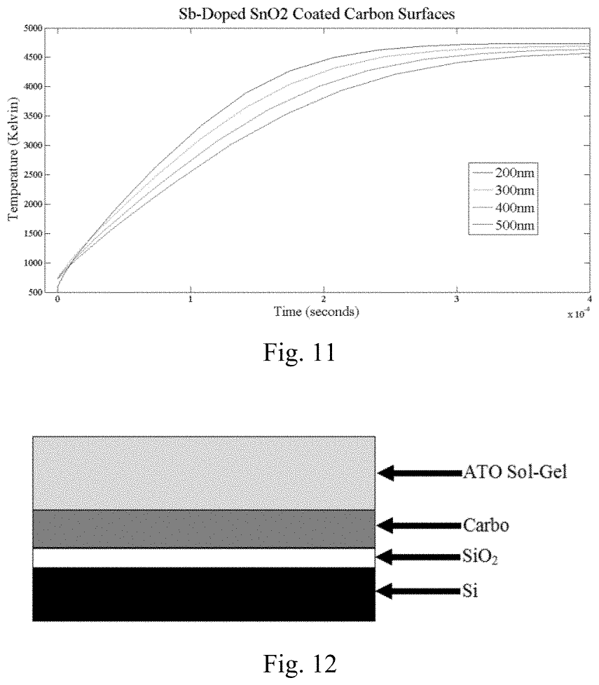

The simulation results shown in FIG. 9 show the effects of temperature change, radiosity, surface irradiation, and reflectivity. FIG. 10 shows simulation parameters using a model that simulates a lamp as a solid object with a volume heat source of 25 kW. The lamp is insulated on all surfaces except for the top, which faces the oxide layer. At this surface, heat leaves the lamp as radiation only. In order to capture the heat source's transient startup time, the model uses a low heat capacity, Cₚ, for the solid (10 J/(kg·K)). In the simulations, it is assumed that the oxide layer dissipates energy via radiation and convection on all surfaces. The temperature probe is placed on the carbon/SnO₂ interface, and the simulation results graphed both temperature and radiation. The thermal material properties were set to parameters set in the COMSOL material database. The point source intensity was raised at 0.1 mW per second. As seen in the plotted results in FIG. 11, the thickness of the tin oxide determined the level of reflectivity. Within 0.05 μs, the different thicknesses reflected various amounts of infrared light.

In another embodiment, metallic nanoparticles can be incorporated into a thin film photovoltaic cell to enhance light wave absorption. The metallic nanoparticles can comprise any suitable metal including silver (Ag) or aluminum (Al).

Ag nanoparticles display both a desirable surface plasmon resonance effect and a plasmon excitation efficiency. On the other hand, Al nanoparticles display optical resonance across a much broader region of the spectrum compared to silver nanoparticles. The metallic nanoparticles can be arranged on a surface of a silicon thin film as an array of closed packed nanospheres.

Following are examples that illustrate procedures for practicing the invention. These examples should not be construed as limiting. All percentages are by weight and all solvent mixture proportions are by volume unless otherwise noted.

### Example 1

The ATO and (ATO(0.1% Co₂O₃)) sol-gel solution was made with a mixture of oxide sol-gel solutions. All of the sol-gels were made with 2-ethylhexanoic acid. The ratio of cobalt and antimony to tin are as follows: Co₂O₃:SnO₂=0.0011:1 and Sb₂O₃:SnO2=10:90.

Silicon wafers having a diameter of 300 mm were cleaned using a standard wafer cleaning process, which removed organics, native oxide layers, and ionic contamination. The wafers were then cut into 1×1 cm² squares. A lead target was used to sputter 10-20 nm of carbon onto the silicon substrate at 50 mTorr. In each deposition, roughly 25 nm of carbon was deposited on a silicon substrate. 20 μL of the sol-gel solution was deposited on the sample surface by spin coating at a rate of 2000 rpm for 20 seconds.

A programmable Vulcan 3-550 box furnace (120 V/12 A) was used to perform the heat treatments. The samples were heat treated in the temperature range of 200-500° C. at atmospheric pressure. In each heat treatment, the samples were ramped up to the specified temperature at a rate of 10° C./min. Three time and temperature intervals were chosen to assure the evaporation of the sol and highest possible sol-gel layer quality. Once reached, the specified temperature was held for 1 hour. The samples were allowed to cool to room temperature for a minimum of 4 hours before testing. FIG. 12 shows a two dimensional layout of the sample.

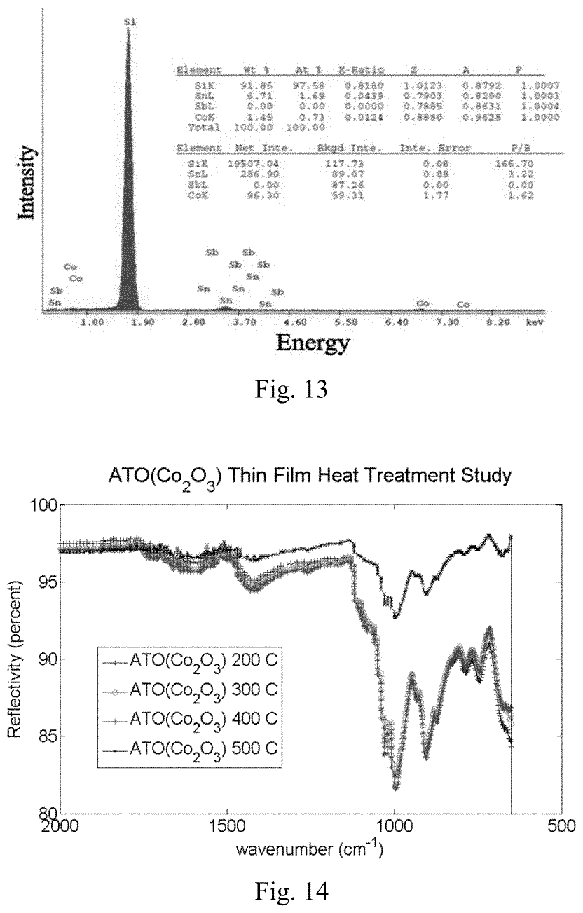

Imaging and energy dispersive X-ray spectroscopy (EDS) were done on a Hitachi S-800 scanning electron microscope with an EDAX-Phoenix EDS detector. FIG. 13 shows no visible single oxygen peaks in the EDS results. This is because the oxygen (O) is at a lower intensity than tin (Sn) and cobalt (Co), which causes the O peaks to be hidden behind the Sn and Co peaks. In the ATO sol gel solution, the oxygen content was added 1-5% relative to Sn, and 0.5% relative to Sb. Co₂O₃ was added at 0.1% relative to this solution.

FTIR spectroscopy was performed to evaluate the effects of heat treatment to the sol-gel reflectivity. As seen in FIG. 14, the heat treatments can be used as a tuning procedure to achieve a specific amount of reflectance. The increase in reflectance by way of the annealing temperature is attributed to the increase in grain size. Specifically, this affect is mainly due to an increase in the thermal energy for crystallization, recrystallization, and growth of grains in the films. Structural parameters, such as dislocation density and the micro-strain are found to show a decreasing trend with increase in annealing temperature, which may be a result of the reduction in the concentration of lattice imperfections. In addition, ATO is oxidative resistant, and band gap tailoring capabilities are controlled by the doping level of Sb and the heat treatment of the sol-gel solution.

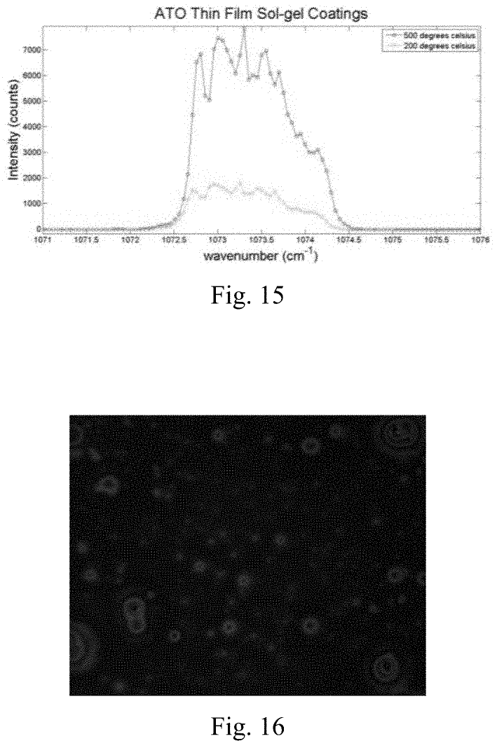

FIG. 15 shows the analysis of the ATO sol-gel thin films heat treated at 200 and 500° C. From the experiments, it is seen in FIG. 15 that the (Sb)SnO₂ coating does, in fact, experience higher lattice vibrations in the crystal lattice due to the performed heat treatment. It is shown that the vibrations in the crystal lattice increase after the heat treatment at 500° C. This is attributed to the increase in grain size growth and shifting of the antimony atoms towards the surface. During the heat treatment, Sb forms ionic bonds with the SnO₂ lattice, substitutionally replacing Sn defects and dislocations.

The change in intensity indicates the polarization change of atoms at the surface. Therefore, it is presumed that the migration of Sb towards the surface and the increased charge carrier mobility of Sn causes the change in grain size boundaries in the ATO thin films annealed at 500° C. as compared to 200° C. Collectively, the increase in reflectivity is correlated to the grain size growth and increase in atom density at lattice sites. As seen in FIG. 16, the coating surface has a dark blue appearance after the heat treatment. Distinctions in between heat treatment and color shade were negligible.

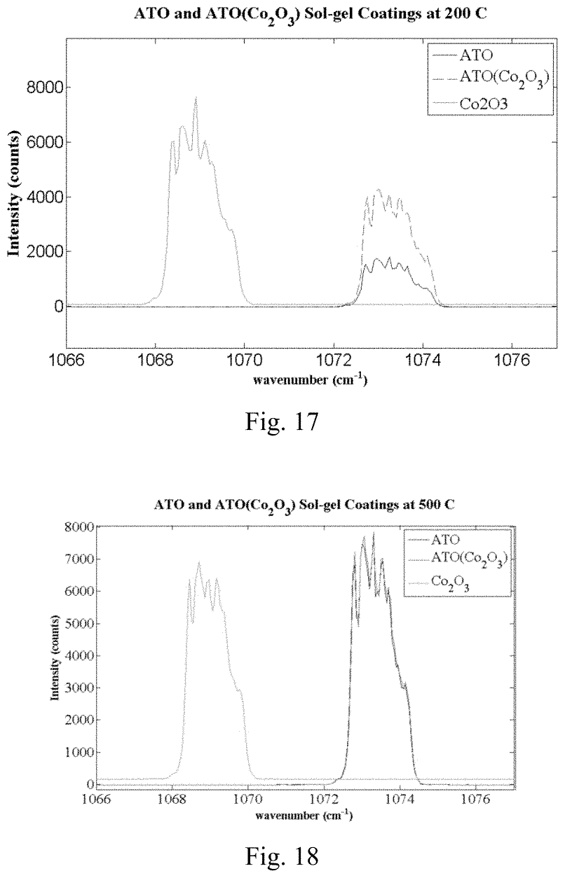

Raman spectroscopy graphs in FIGS. 17 and 18 show undoped ATO, Co2O3, and (ATO (0.1% Co₂O₃)) after 200 and 500° C., respectively. Both (ATO(0.1% Co₂O₃)) samples after 200 and 500° C. heat treatments showed high vibrations in the lattice in the 1072-1075 cm⁻¹ range. The Co₂O₃ sol-gel thin film remains consistent throughout the heat treatment range. After heat treatment on the (ATO(0.1% Co₂O₃)) samples, the Sb and Co atoms form ionic bonds. The intensity change of ATO and (ATO(0.1% Co₂O₃)) at higher heat treatment temperatures indicates the polarization change of atoms present at the surface. When photons collide with the lattice points, fewer electrons at a lower energy level are observed.

The increase in wavelengths is directly proportional to the increase of reflectivity of Co₂O₃. During the recombination and process, Sb and Co are diffused through the crystal structure by way of Sn dislocations and O deficiencies, Sb³⁺ ions segregate towards the surface. Previous studies have implied that Co²⁺ substitute the Sn²⁺ ions and O octahedral coordinated cation sites. Therefore, it is presumed that the Co atoms at the surface cause the slower rate of grain size increase in the (ATO(0.1% Co₂O₃)) thin films at 500° C. as compared to 200° C.

During the heat treatment, the crystal structure is deformed, and Sn³⁺ ions create dislocations and defects in the crystal structure. Concurrently, the grain sizes of Sn and Sb increase, causing a higher percentage of reflectivity. The addition of Co₂O₃ appears to slow the grain size growth at ˜500° C., as opposed to the undoped ATO thin film that has comparable reflectivity at this temperature. This reaction is attributed to the Sb³⁺, Sb⁵⁺, and Co²⁺ ions replacing Sn³⁺ ions in the lattice structure. The substitution of Sn ions for Sb and Co ions is possible because of the similar ionic radii (Sn=0.071 nm, Sb=0.065 nm, and Co=0.071 nm).

### Example 2

The (ATO(x % Co₂O₃)) sol-gel solutions were made with a mixture of oxide sol-gel solutions. All of the sol-gels were made with 2-ethylhexanoic acid. The ratio of cobalt and antimony to tin are as follows: Co₂O₃:SnO₂=0.0011:1 and Sb₂O₃:SnO₂=10:90. Tin alkoxides were used as the salt and an acid was used as the base/solvent for the solution.

In comparison to using tin chlorides as the salt, this method reduces the risk of having residual ions from the acid/solvent (particularly chlorine) being left on the surface and influencing the changes in optical properties. 3×3 inch squares of 0°/90° woven carbon nanofiber mats were immersed in a methanol and acetone wash for 30 minutes, to remove any post manufacturing coating.

The nanofiber mats were allowed to dry in air for 2 hours and where then immersed in 2 mL of the ATO solution. After 2 hours of immersion, the nanofibers where then heat treated in a programmable oven (120 volts/12 amps) at 250° C. at atmospheric pressure. In each heat treatment, the temperature was increased to 75° C. for one hour and then increased until 250° C. was reached, to induce the slow removal of the solvent and decrease the possibility of combustion. This step was also implemented to increase the sol-gel layer quality. Once reached, the specified maximum temperature was held for 1 hour. The samples were allowed to cool to room temperature for a minimum of 4 hours before testing.

4×2 inch quartz slides were also prepared using the same procedure for transmittance tests discussed below with the optical analysis results. Hemispherical measurements were conducted on an OL-70 Integrating Sphere Reflectance Attachment. A fixed incident angle of 10° was set to measure over a wavelength range of 900-1100 nm. A 1″ diameter piece of Labsphere 99% spectralon was used as the reflectance standard. For the angular-dependent reflectance, a Bio-Rad FTS 6000 FTIR system was modified to use the embedded Nd:YAG laser (1.064 μm). Two separate experiments were conducted. First, ATO(x % Co₂O₃) sol-gel coated glass slides were placed at a fixed angle of 0°. This process was completed to investigate the transmittance and reflectivity of the sol-gel coatings independently of the carbon nanofiber mats. Secondly, the specular angle was found around 90° in respect to the laser source. Once the specular angle was found, the incident angle was altered ±10° in 5° steps, giving 80°, 85°, 90°, 95°, and 100° incident angle recordings, which is listed in Table I.

For both experiments, the spectra range was set to 0.7-2.3 μm. 32 scan steps were completed on each sample and then integrated into a reading for that particular wavelength. Three measurements at different spatial locations were made on each sample to account for non-uniformities and defects in the surfaces. These measurements were then averaged to provide the documented reflectance results. Each spectrometer run consisted of two modes: comparison and run. Inside the spectrometer system, a mirror was used to rotate in between a specified section of the sphere and the opening where the sample was placed. The detector acted as a photodiode and gave readouts in units of amperage. For each measurement, a reference measurement was first made from the reflected light, or current, that was collected by the detector. Next, the mirror was switched to reflect light from the sample.

TABLE I

| Measurement Angle | Degree from Specular Angle |
|---|---|
| 80° | −10° |
| 85° | −5° |
| 90° | 0° |
| 95° | 5° |
| 100° | 100° |

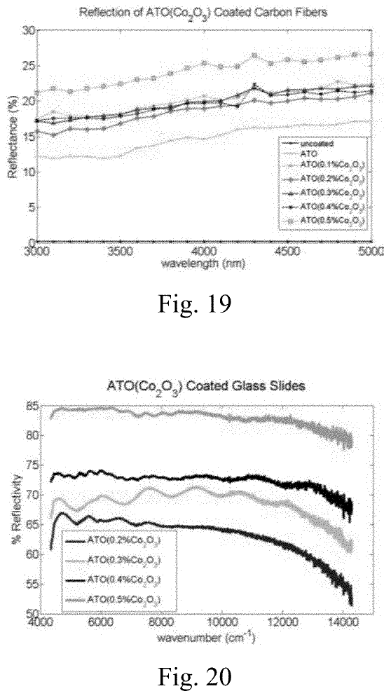

The resulting reflectivity readout was calculated by the ratio of the comparison and run mode amperage readings, giving reflectivity points from 0 to 1. To report the data in terms of percentage, the data points are multiplied by 100. If light passes through the sample, this affects the reading and results in an error. To correct this issue, samples were stacked and placed in a (0°/90°)-(+/−45°) layup scheme to minimize the possibility of light passing through the sample. As seen in FIG. 19, the reflectivity increases directly proportional to the increased percentage of Co₂O₃. As hypothesized, the bulk material measurements did not directly correlate to the thin film measurements.

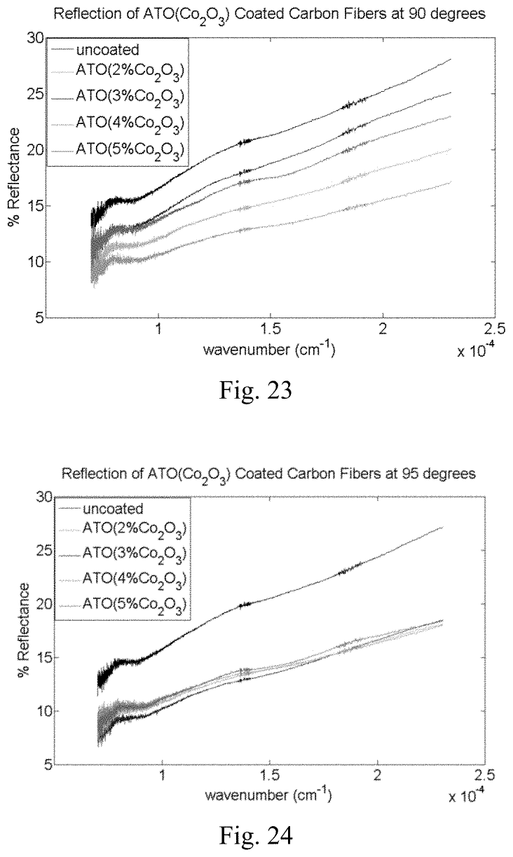

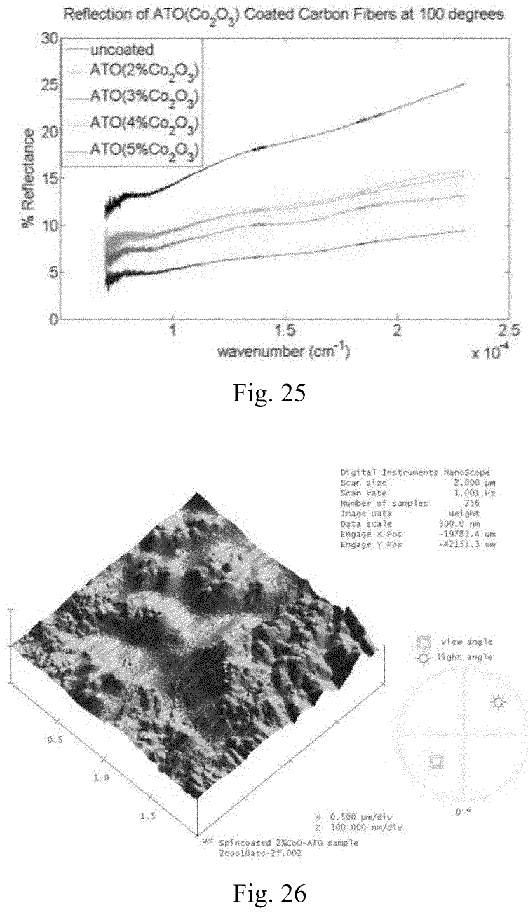

The variation in the reflectivity of the samples is seen in FIGS. 20 through 25. FIG. 20 shows the reflectance data collected from the sol-gel coated glass slides. Next, the (ATO(x % Co₂O₃)) sol-gel coated carbon nanofiber mats were placed in a bistatic detection setup, in which the signal source was placed at an angle in reference to the detector.

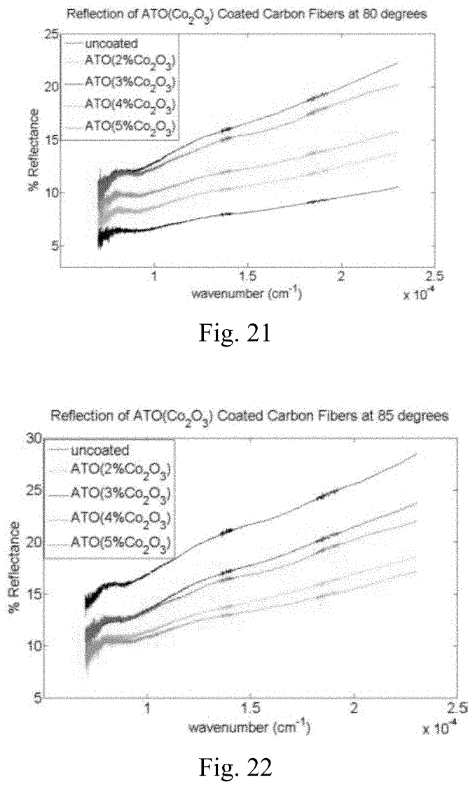

Thin films of the (ATO(x % Co₂O₃)) can sustain a range of 50-80% reflectivity in the 0.7 to 2.3 μm spectral range. Interestingly, (ATO(2% Co₂O₃)) approaches 85% reflectivity, giving the highest result. The influence of the added of Co₂O₃ begins to decrease the reflectivity at doping levels higher than 0.3%. FIGS. 21 through 25 show that the addition of Co₂O₃ causes decreased grain growth once doped at a level higher than 0.3%. Co₂O₃ doping levels above this limit appear to saturate the ATO and begin to degrade the reflectivity. The beam size of the laser source was roughly three inches in circumference. Because of this, effects from defects in the sol-gel coatings as well as the carbon nanofiber mat's rigid, conformal surface where negligible. For the hemispherical spectroscopy, the tests were performed at atmospheric pressure in ambient air. Because of this, there was a large dip present in the comparison modes measurements at 4.2 microns. Inside the Au sphere, the standard sample surface was 97-98% reflective. The specular plugin was also used to keep the specular component integrated into the diffused component. The calibration baseline of the uncoated carbon nanofiber mat gave a reflectivity reading of ˜0.2%. During the readings, the infrared light source was kept at 6 amperes to reduce the signal to noise ratio. This compensation did not compromise the readings.

### Example 3

Samples with varying concentrations of cobalt oxide and antimony doped tin oxide were made as thin films on silicon solar cells. The doping percentages of cobalt oxide in antimony doped tin oxide was 4%, 8%, 12%, and 16% by weight, as seen in Table II. Solar cells were scribed and spin coated with these solutions. Copper contacts were taped down and placed under bright sunlight and open circuit voltage and short circuit current were measured.

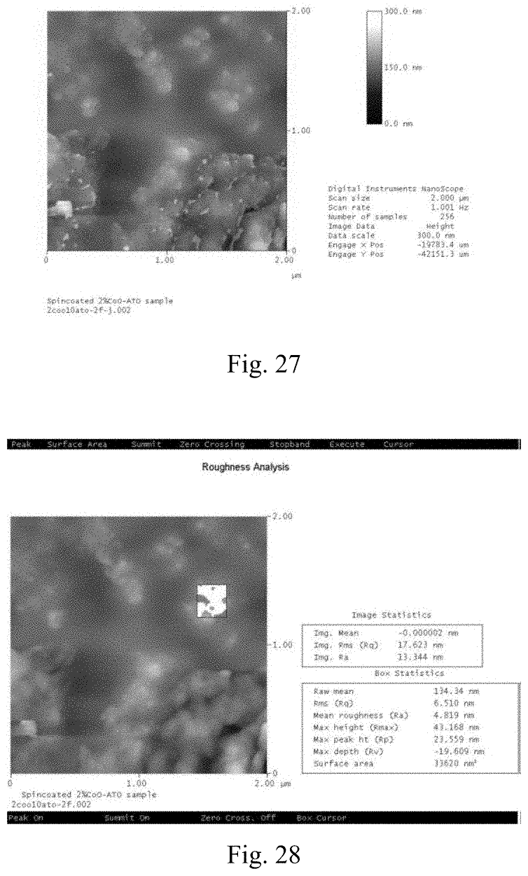

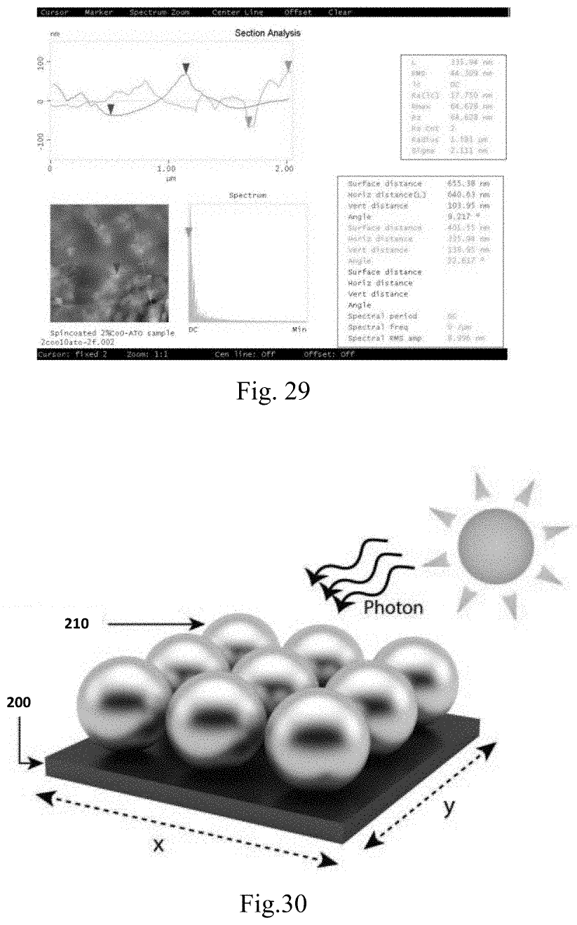

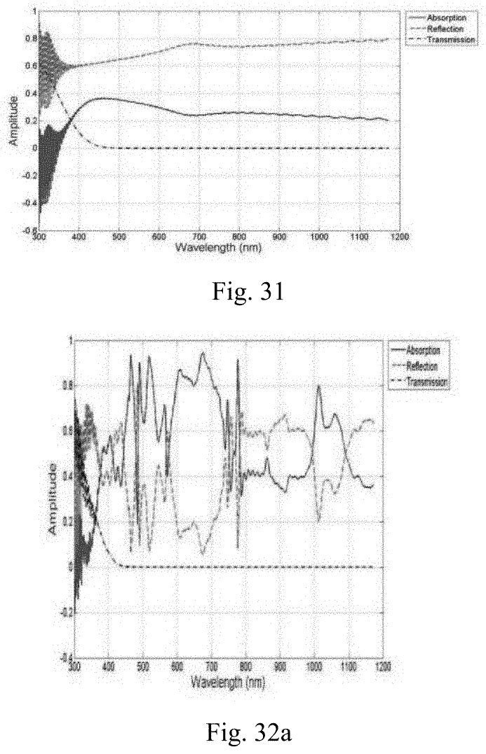

Thin film samples were thoroughly dried in a drying chamber and used to obtain atomic force spectroscopy readings, as seen in FIGS. 26-29. From the measured short circuit current and the open circuit voltage, the power produced was calculated. The obtained results show that sample 4, in which 16% by weight of cobalt oxide and 94% by weight antimony doped tin oxide was used, produced the maximum wattage.

### Example 4

Silver and aluminum nanospheres were used to improve the energy conversion efficiency of a plasmonic solar cell. The Ag and Al nanospheres were respectively placed on top of silicon thin films.

A typical flat silicon film structure 200, as seen in FIG. 30, was used as a control reference. The thickness of the silicon thin film used in the model was 3 μm, and its length (x) and width (y) were both 0.50 μm. Silver or aluminum nanospheres 210 were situated on the surface of the silicon thin film. Silicon shows dispersive nature in the range of 1.1 eV to 4.13 eV which corresponds to 265 THz to 1000 THz. An experimentally measured optical constant was used to construct this particular dispersion model of silicon.

The optical constants were interpolated using an n^{th} order dispersion model by calculating the complex refractive index e′ and e″ using equations:

ε′=n²−k² (1)

ε″=2nk (2)

TABLE II

| | Percentage by weight of | Percentage by weight of |
|---|---|---|
| Sample number | CoO (%) | ATO (%) |
| 1 | 4 | 96 |
| 2 | 8 | 92 |
| 3 | 12 | 88 |
| 4 | 16 | 84 |

TABLE III

| Sample number | V_{oc} (V) | Isc (A) | Power (W) |
|---|---|---|---|
| 1 | 0.558 | 1.077 | 0.600 |
| 2 | 0.556 | 1.084 | 0.602 |
| 3 | 0.520 | 1.200 | 0.624 |
| 4 | 0.537 | 1.460 | 0.784 |

TABLE IV

| Frequency (Hz) | ε′ | ε″ |
|---|---|---|
| 3.628 × 10¹⁴ | −61.5 | 45.60 |
| 3.750 × 10¹⁴ | −45.7 | 28.10 |
| 4.000 × 10¹⁴ | −47.5 | 25.60 |
| 4.286 × 10¹⁴ | −46.6 | 21.70 |
| 4.615 × 10¹⁴ | −42.0 | 16.40 |
| 4.839 × 10¹⁴ | −54.2 | 19.50 |
| 5.000 × 10¹⁴ | −35.1 | 11.60 |
| 5.455 × 10¹⁴ | −27.7 | 08.90 |
| 6.000 × 10¹⁴ | −22.7 | 05.95 |
| 6.6777 × 10¹⁴ | −18.4 | 04.23 |
| 7.500 × 10¹⁴ | −15.2 | 03.14 |

From the simulation, the transmission and reflection coefficient were obtained and absorption efficiency was calculated. The model was designed and simulated in a computer based simulation environment. The transmission and reflection coefficient of a single unit was recorded. A polarized plane wave source was used to imitate the solar illumination with boundary conditions X=electric (Et=0), Y=Magnetic (Ht=0), Z=open. Nanospheres having four different radii were used in the simulations. Each time the simulation was performed with a different chosen radius. For the Ag nanospheres, the Drude dispersion model was applied. For the Al nanospheres, the dispersive nature of aluminum within visible range was considered. The Drude model for permittivity of silver is defined as:

$${ϵ}_{0} ( ω ) = {ϵ}_{∞} - \frac{{ω}_{p}^{2}}{{ω}^{2} + i ω y} , \qquad ( 3 )$$

in which

$${ω}_{p}^{2} = \frac{{ne}^{2}}{{ϵ}_{0} {m}_{ϵ}} [ Plasma Frequency ] , and \\ {ϵ}_{∞} = 4.968 , \\ {ω}_{p} = 1.4497 \times {10}^{16} rad / s \\ Γ = 8.33689 \times {10}^{12} / s . \qquad ( 4 )$$

The absorption efficiency enhancement was quantified using the ultimate efficiency defined as follows:

$$η = \frac{{\int }_{300 nm}^{{λ}_{g}} I ( λ ) A ( λ ) \frac{λ}{{λ}_{g}} d λ}{{\int }_{300 nm}^{4000 nm} I ( λ ) d λ } \qquad ( 5 )$$

where λ is the wavelength and λ_{g} is the wavelength corresponding to the band gap of silicon. I(λ) is the ASTM AM1.5 solar spectral irradiance and A(λ) is the overall absorbance of the plasmonic nano sphere. For ultimate efficiency calculation, the Simpson 3/8 rule was used.

The absorption of the proposed thin film plasmonic solar cell was calculated with the energy balance equation. From the conservation of energy it follows that:

R(ω)+A(ω)+T(ω)=1, (6)

hence the absorption of the plasmonic structure is given by

A(ω)=1−R(ω)−T(ω). (7)

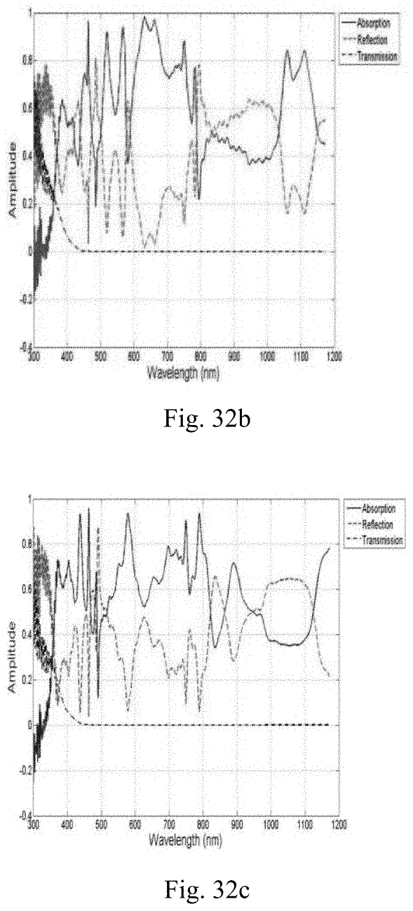

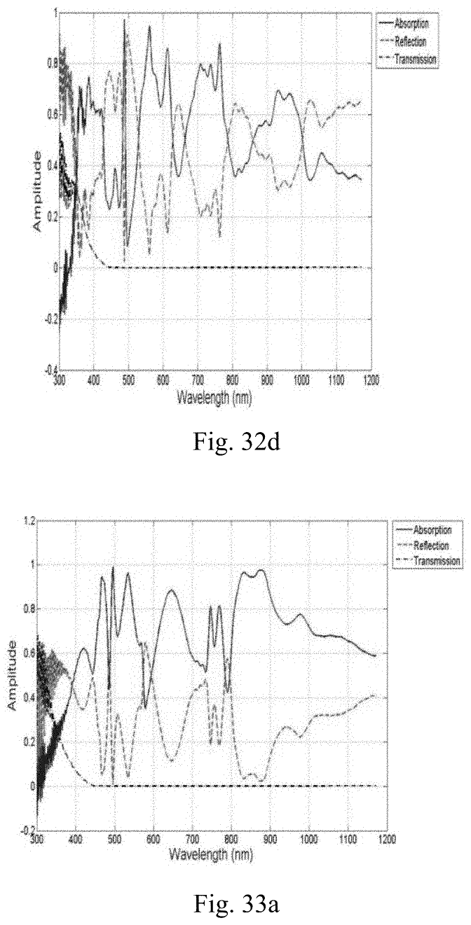

The absorption and absorption efficiency are calculated using equation (5) and (7). The absorption efficiency of the 3 μm thin film was calculated at 9.74%. FIGS. 32a-32d show the transmission coefficient, reflection coefficient and the corresponding absorption of 3 μm silver nanosphere of diameter 167 nm, 180 nm, 200 nm and 220 nm.

The absorption efficiencies of the thin film silicon plate with embedded silver nanospheres were calculated using equation (5). The efficiencies are presented in Table V.

TABLE V

Diameter of Ag
nanosphere (nm)

| | 167 | 180 | 200 | 220 |
|---|---|---|---|---|
| Absorption | 19.47 | 20.09 | 22.48 | 21.62 |
| efficiency (%) | | | | |

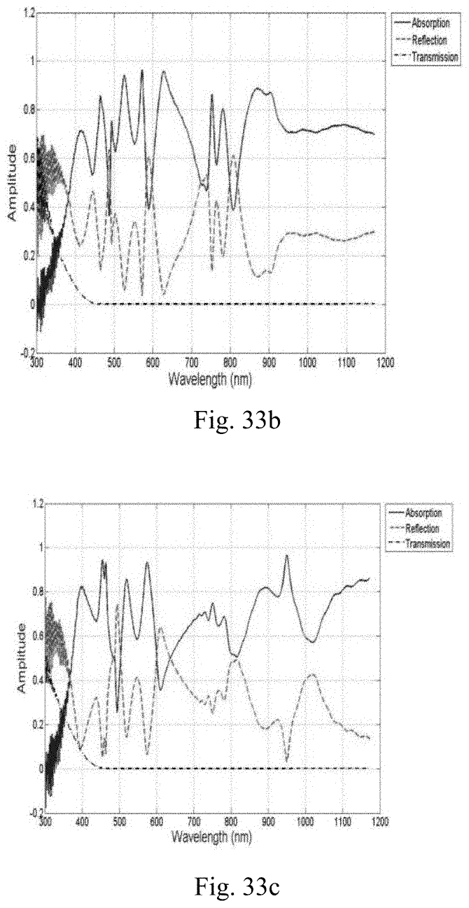

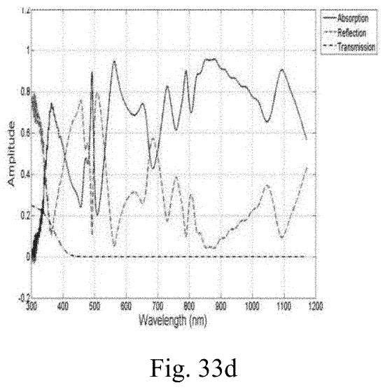

FIGS. 33a-33d show the transmission coefficient, reflection coefficient and the corresponding absorption of a 3 μm aluminum nanosphere of diameter 1167 nm, 180 nm, 200 nm, and 220 nm. The absorption efficiencies of the thin film silicon plate with Al nanospheres were calculated using equation (5). The efficiencies are presented in Table VI.

The proposed model demonstrates that the optical characteristics of metallic nanospheres are strongly dependent on the size, shape, and the type of metal used. It also confirmed light absorption enhancement with 167 nm, 180 nm, 200 nm, and 220 nm Ag or Al nanospheres over a3 μm silicon thin film. The highest absorption efficiency was obtained using 200 nm nanospheres in both the cases. The thin film silicon solar cell displayed an absorption efficiency of 9.74% whereas the thin film with Ag nanospheres having a radius 200 nm had an absorption efficiency that increased to 22.48% and the thin film with Al nanospheres having a radius of 200 nm had an absorption efficiency that increased to 24.06%.

TABLE VI

Diameter of Al
nanosphere
(nm)

| | 167 | 180 | 200 | 220 |
|---|---|---|---|---|
| Absorption | 21.27 | 22.15 | 24.06 | 23.58 |
| efficiency (%) | | | | |

It should be understood that the examples and embodiments described herein are for illustrative purposes only and that various modifications or changes in light thereof will be suggested to persons skilled in the art and are to be included within the spirit and purview of this application. In addition, any elements or limitations of any invention or embodiment thereof disclosed herein can be combined with any and/or all other elements or limitations (individually or in any combination) or any other invention or embodiment thereof disclosed herein, and all such combinations are contemplated with the scope of the invention without limitation thereto.

All patents, patent applications, provisional applications, and publications referred to or cited herein are incorporated by reference in their entirety, including all figures and tables, to the extent they are not inconsistent with the explicit teachings of this specification.

1-16. (canceled)

17. A metallic nanoparticle coated optoelectronic device, comprising:
a thin film silicon substrate; and
a layer of metallic nanospheres coated on a surface of the thin film silicon substrate.

18. The metallic nanoparticle coated optoelectronic device according to claim 17, wherein the metallic nanospheres comprise silver or aluminum.

19. The metallic nanoparticle coated optoelectronic device according to claim 18, wherein each of the metallic nanospheres has a respective radius in a range of 167 nm to 220 nm.

20. The metallic nanoparticle coated optoelectronic device according to claim 19, wherein the thin film silicon substrate has a thickness of 3 μm.

21. The metallic nanoparticle coated optoelectronic device according to claim 17, wherein each of the metallic nanospheres has a respective radius in a range of 167 nm to 220 nm.

22. The metallic nanoparticle coated optoelectronic device according to claim 17, wherein the thin film silicon substrate has a thickness of 3 μm.

23. The metallic nanoparticle coated optoelectronic device according to claim 17, wherein the metallic nanospheres comprise aluminum.

24. The metallic nanoparticle coated optoelectronic device according to claim 17, wherein the metallic nanospheres comprise silver.

25. The metallic nanoparticle coated optoelectronic device according to claim 17, wherein the metallic nanospheres are arranged as a packed array on the surface of the thin film silicon substrate.

26. The metallic nanoparticle coated optoelectronic device according to claim 17, wherein each of the metallic nanospheres has a respective radius of 200 nm.

27. The metallic nanoparticle coated optoelectronic device according to claim 17, wherein the metallic nanospheres comprise silver or aluminum,
wherein the thin film silicon substrate has a thickness of 3 μm.
wherein the metallic nanospheres are arranged as a packed array on the surface of the thin film silicon substrate, and
wherein each of the metallic nanospheres has a respective radius of 200 nm.

28. A metallic nanoparticle coated optoelectronic device, comprising:
a thin film silicon substrate; and
a layer of aluminum metallic nanospheres coated on a surface of the thin film silicon substrate,
wherein each of the aluminum metallic nanospheres has a respective radius in a range of 167 nm to 220 nm.

29. The metallic nanoparticle coated optoelectronic device according to claim 28, wherein the thin film silicon substrate has a thickness of 3 μm.

30. The metallic nanoparticle coated optoelectronic device according to claim 28, wherein the aluminum metallic nanospheres are arranged as a packed array on the surface of the thin film silicon substrate.

31. The metallic nanoparticle coated optoelectronic device according to claim 28, wherein each of the aluminum metallic nanospheres has a respective radius of 200 nm.

32. The metallic nanoparticle coated optoelectronic device according to claim 28, wherein an absorption efficiency of the metallic nanoparticle coated optoelectronic device is over 24%.

33. A metallic nanoparticle coated optoelectronic device, comprising:
a thin film silicon substrate; and
a layer of silver metallic nanospheres coated on a surface of the thin film silicon substrate,
wherein each of the silver metallic nanospheres has a respective radius in a range of 167 nm to 220 nm.

34. The metallic nanoparticle coated optoelectronic device according to claim 33, wherein the thin film silicon substrate has a thickness of 3 μm.

35. The metallic nanoparticle coated optoelectronic device according to claim 33, wherein the silver metallic nanospheres are arranged as a packed array on the surface of the thin film silicon substrate.

36. The metallic nanoparticle coated optoelectronic device according to claim 33, wherein each of the silver metallic nanospheres has a respective radius of 200 nm.
